(19) United States
(12) Patent Application Publication
(10) Pub. No.: US 2020/0096570 A1
(43) Pub. Date: Mar. 26, 2020

(54) DESIGN METHOD FOR SCAN TEST CIRCUIT, DESIGN PROGRAM FOR SCAN TEST CIRCUIT AND SEMICONDUCTOR INTEGRATED CIRCUIT

(71) Applicants: Kabushiki Kaisha Toshiba, Tokyo (JP); Toshiba Electronic Devices & Storage Corporation, Tokyo (JP)

(72) Inventor: Chikako Tokunaga, Yokohama Kanagawa (JP)

(21) Appl. No.: 16/294,055

(22) Filed: Mar. 6, 2019

(30) Foreign Application Priority Data
Sep. 20, 2018 (JP) 2018-176117

(51) Int. Cl. G01R 31/3185; H01L 27/02; G06F 17/50

(52) U.S. Cl. CPC G01R 31/318591; H01L 27/0207; G01R 31/318594; G06F 17/5081; G06F 17/505; G06F 17/5077; G06F 17/5072; G01R 31/318547

(57) ABSTRACT

A design method for a scan circuit includes reading timing constraint information, a net list and layout information, to extract a multicycle path route from routes existing in a semiconductor integrated circuit, dividing the multicycle path route extracted by a number of cycles, and adding a test circuit at each of locations divided by the number of cycles.

### CROSS-REFERENCE TO RELATED APPLICATION

This application is based upon and claims the benefit of priority from the prior Japanese Patent Application No. 2018-176117 filed on Sep. 20, 2018; the entire contents of which are incorporated herein by reference.

### FIELD

Embodiments described herein relate generally to a design method for a scan test circuit, a design program for a scan test circuit and a semiconductor integrated circuit.

### BACKGROUND

In an automatic test pattern generator (ATPG) taking timing constraint into consideration, multicycle path routes have been conventionally excluded from targets of ATPG depending on tools. In recent years, tools allowing the multicycle path routes to be treated as targets of ATPG have been known, but many troubles have occurred, and also a problem that a failure detection rate is not increased has existed.

### BRIEF DESCRIPTION OF THE DRAWINGS

FIG. 1 is a block diagram showing a configuration of an information processing device according to a first embodiment;

FIG. 2 is a flowchart illustrating a processing procedure of a design program 106;

FIG. 3 is a diagram showing an example of a scan test circuit according to the first embodiment;

FIG. 4 is a diagram showing an example of a semiconductor integrated circuit having the scan test circuit according to the first embodiment;

FIG. 5 is a diagram showing an example of a scan test circuit according to a modification of the first embodiment;

FIG. 6 is a diagram showing an example of a scan test circuit according to a second embodiment; and

FIG. 7 is a diagram showing an example of a scan test circuit according to a modification of the second embodiment.

### DETAILED DESCRIPTION

A design method for a scan circuit according to an embodiment reads timing constraint information, a net list and layout information to extract a multicycle path route from routes existing in a semiconductor integrated circuit, divides the multicycle path route extracted by a number of cycles, and adds a test circuit at each of locations divided by the number of cycles.

Embodiments will be described hereunder in detail with reference to the drawings.

### First Embodiment

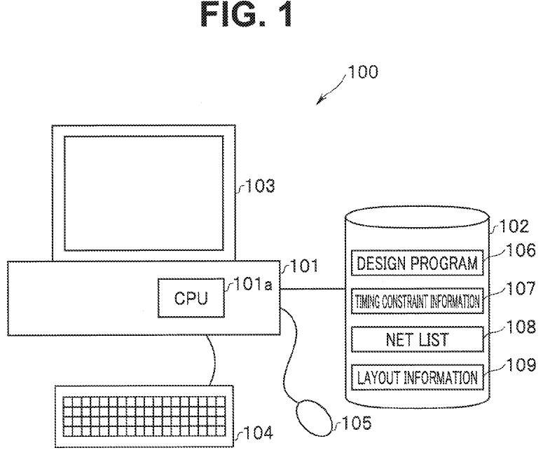

First, a configuration of an information processing device according to a first embodiment will be described with reference to FIG. 1. FIG. 1 is a block diagram showing the configuration of the information processing device according to the first embodiment. As shown in FIG. 1, the information processing device 100 is, for example, a personal computer, and configured to include a main body device 101, a storage device 102, a display device 103, a keyboard 104, and a mouse 105. Furthermore, the main body device 101 is configured to have a central processing unit (hereinafter referred to as a CPU) 101a. The keyboard 104 and the mouse 105 as input devices are configured to be connected to the main body device 101.

A design program 106 fir designing a scan test circuit is stored in the storage device 102. In addition, timing constraint information 107, a net list 108, and layout information 109 are stored in the storage device 102. A user can design a scan test circuit described later by operating the keyboard 104 and the mouse 105 to read the timing constraint information 107, the net list 108 and the layout information 109 and also executing the design program 106 on the CPU 101a.

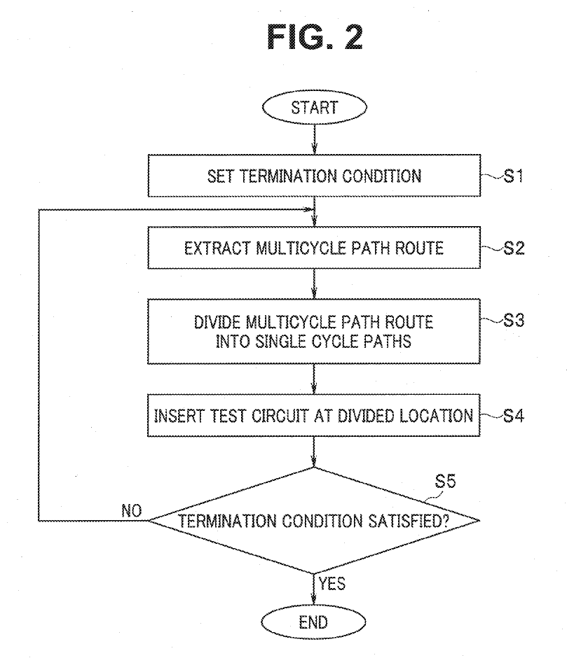

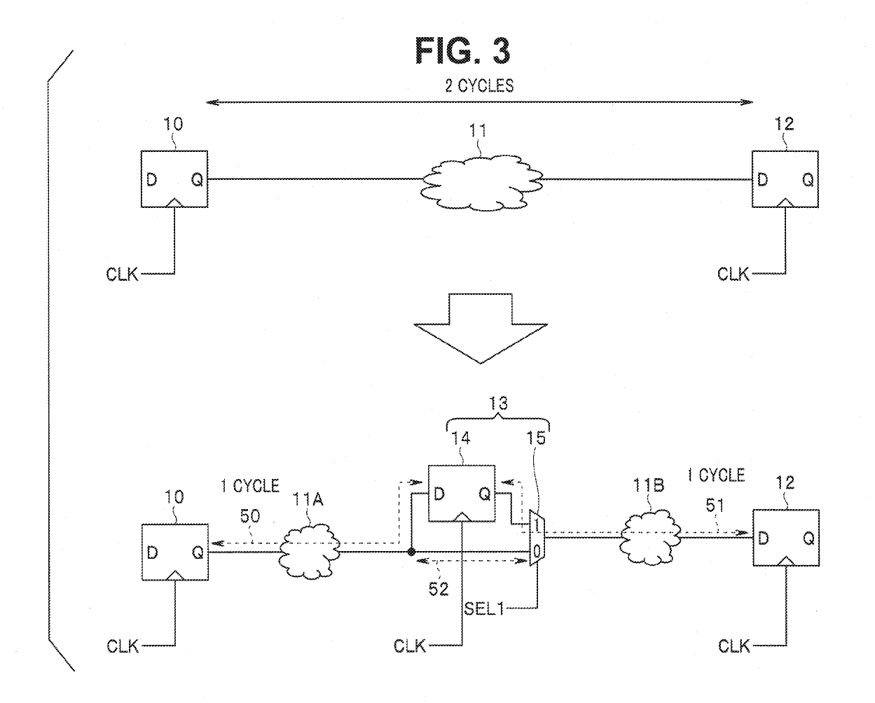

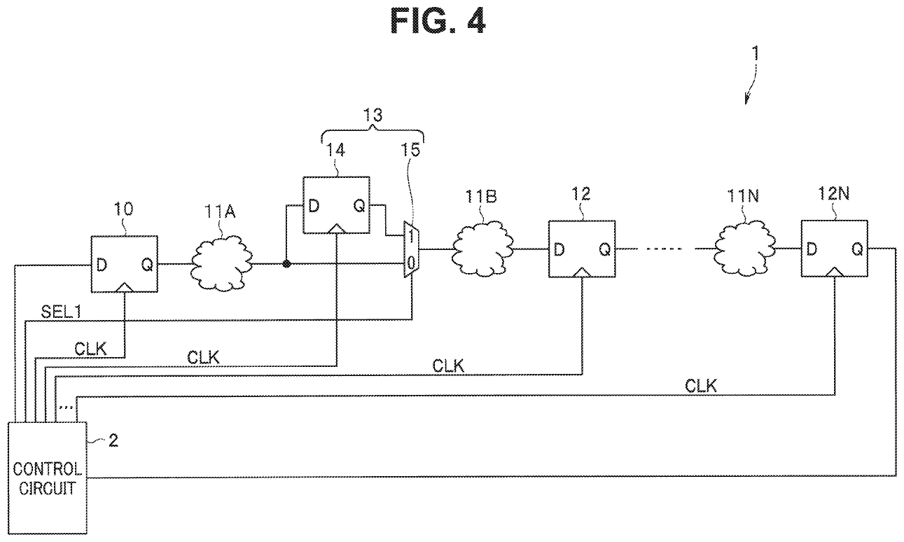

Here, a processing procedure of the design program 106 will be described with reference to FIG. 2. FIG. 2 is a flowchart illustrating the processing procedure of the design program 106. FIG. 3 is a diagram showing an example of the scan test circuit according to the first embodiment, and FIG. 4 is a diagram showing an example of a semiconductor integrated circuit having the scan test circuit according to the first embodiment.

First, a termination condition is set by the user (S1). The user can change the termination condition to a desired condition by using, for example, the keyboard 104 and the mouse 105 as the input devices. A default value of the termination condition is “Have all multicycle path routes been extracted?” if the user does not set (change) the termination condition, the termination condition is “Have all multicycle path routes been extracted?”

Next, the user reads the timing constraint information 107, the net list 108, and the layout information 109 from the storage device 102 and executes the design program 106, so that the CPU 101a extracts multicycle path routes from the routes of the semiconductor integrated circuit (S2).

Specifically, as shown in FIG. 3, the CRU 101a extracts a multicycle path route requiring multiple clocks for propagation of data between flip-flops 10 and 12 in a circuit configuration including the flip-flop 10, a combinational circuit 11, and the flip-flop 12. Note that in the example in FIG. 3, although the route including the flip-flop 10, the combinational circuit 11 and the flip-flop 12 is based on 2 cycles, the CPU 101a also extracts routes based on 3 or more cycles.

Next, the CPU 101a divides the multicycle path route into single-cycle paths (S3). Specifically, the CPU 101a divides the multicycle path route by the number of cycles. In the present embodiment, since the route including the flip-flop 10, the combinational circuit 11, and the flip-flop 12 is based on 2 cycles, the multicycle path route is divided into two parts. Therefore, as shown in FIG. 3, the CPU 101a divides the combinational circuit 11 into two combinational circuits, that is, a combinational circuit 11A and a combinational circuit 11B.

Next, the CPU 101a inserts a test circuit at a divided location (S4). Specifically, as shown in FIG. 3, the CPU 101a inserts a test circuit 13 between the combinational circuit 11A and the combinational circuit 11B. The test circuit 13 is configured by a flip-flop 14 and a multiplexer 15. As a result, single-cycle paths (1 cycle) are configured between the flip-flop 10 and the flip-flop 14 and between the flip-flop 14 and the flip-flop 12, respectively.

Note that when the route including the flip-flop 10, the combinational circuit 11, and the flip-flop 12 is based on 3 cycles, the CPU 101a divides the multicycle path route into three paths, and inserts the test circuit 13 at each divided location.

An output of the combinational circuit 11A is input to an input terminal of the flip-flop 14, and also input to one input terminal of the multiplexer 15. An output of the flip-flop 14 is input to the other input terminal of the multiplexer 15. An output of the multiplexer 15 is input to an input terminal of the combinational circuit 11B.

Based on a selection signal SEL1, the multiplexer 15 outputs one of the output of the combinational circuit 11A and the output of the flip-flop 14 to the combinational circuit 11B. More specifically, when the selection signal SEL1 is equal to “0”, the multiplexer 15 outputs the output of the combinational circuit 11A to the combinational circuit 11B, and when the selection signal SEL1 is equal to “1”, the multiplexer 15 outputs the output of the flip-flop 14 to the combinational circuit 11B.

When “1” is input as the selection signal SEL1 to the multiplexer 15, a transition test as to whether data transits Within a predetermined delay time period can be performed on the combinational circuit 11A between the flip-flop 10 and the flip-flop 14. When “1” is input as the selection signal SEL1 to the multiplexer 15, the transition test can be likewise performed on the combinational circuit 11B between the flip-flop 14 and the flip-flop 12. That is, when “1” is input as the selection signal SEL1 to the multiplexer 15, it is possible to perform failure detection of a wiring 50 between the flip-flop 10 and the flip-flop 14 and a wiring 51 between the flip-flop 14 and the flip-flop 12. When the semiconductor integrated circuit 1 is used as a system, “0” may be input as the selection signal SEL1 to the multiplexer 15.

Finally, the CPU 101a makes a termination determination. Specifically, the CPU 101a determines whether the termination condition set in S1 has been satisfied (S5). If the CPU 101a determines that the termination condition set in S1 has not been satisfied (S5: NO), the CPU 101a returns to the processing of S2 to repeat the same processing. On the other hand, when determining that the termination condition set in S1 has been satisfied (55: YES), the CPU 101a terminates the processing.

A semiconductor integrated circuit 1 shown in FIG. 4 is configured to include a control circuit 2, multiple combinational circuits 11N, and multiple flip-flops 12N in addition to the scan test circuit of FIG. 3.

The control circuit 2 controls the entire semiconductor integrated circuit 1. For example, the control circuit 2 supplies clocks CLK to the flip-flops 10, 12, and 12N, and supplies the selection signal SEL1 to the multiplexer 15.

Through the above processing, all multicycle paths of the semiconductor integrated circuit 1 are divided into single-cycle paths, and the test circuit 13 is inserted at each divided location. As a result, the transition test as to whether data transits within a predetermined delay time period can be performed on the combinational circuit 11A between the flip-flop 10 and the flip-flop 14 and the combinational circuit 1113 between the flip-flop 14 and the flip-flop 12.

As a result, for each of the divided paths, for example, in the example of FIG. 3, failure detection can be performed on each of the wiring 50 and the wiring 51, and the failure detection can be performed as an entire path. In FIG. 3, since a wiring 52 is sufficiently short, the timing of the wiring 52 is negligible.

Therefore, according to the design method for the scan test circuit of the present embodiment, it is possible to increase the failure detection rate of the multicycle path route.

### (Modification)

Next, a modification of the first embodiment will be described. In the first embodiment, the wiring 52 is excluded from targets of the transition test. However, in the modification, a scan test circuit which enables all wirings of a multicycle path to be subjected to the transition test will be described.

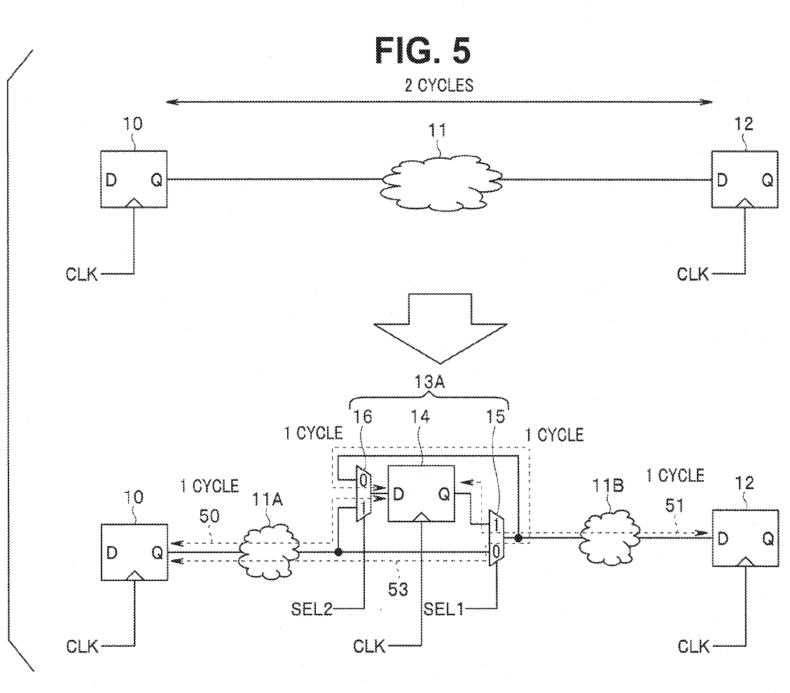

FIG. 5 is a diagram showing an example of the scan test circuit according to the modification of the first embodiment. Note that in FIG. 5, components similar to the components in FIG. 3 are represented by the same reference signs, and description on the components is omitted.

A test circuit 13A according to the modification of the first embodiment is configured by adding a multiplexer 16 to the flip-flop 14 and the multiplexer 15 of the test circuit 13 of FIG. 3. An output of the combinational, circuit 11A is input to one input terminal of the multiplexer 16, and an output of the multiplexer 15 is input to the other input terminal of the multiplexer 16. Based on a selection signal SEL2, the multiplexer 16 outputs the output of the combinational circuit 11A or the output of the multiplexer 15 to the flip-flop 14.

More specifically, when the selection signal SEL2 is equal to “0”, the multiplexer 16 outputs the output of the multiplexer 15 to the flip-flop 14, and when the selection signal SEL2 is equal to “1”, the multiplexer 16 outputs the output of the combinational circuit 11A to the flip-flop 14.

When “1” is input as the selection signals SE1 and SEL2 to the multiplexers 15 and 16, it is possible to perform the transition test on the wiring 50 between the flip-flop 10 and the flip-flop 14 and the wiring 51 between the flip-flop 14 and the flip-flop 12 as in the case of the first embodiment.

On the other hand, when “0” is input as the selection signals SEL1 and SEL2 to the multiplexers 15 and 16, the route including the flip-flop 10, the multiplexer 15, the multiplexer 16 and the flip-flop 14 becomes effective, and the transition test on a wiring 53 is enabled. Note that in order to realize the transition test on the wiring 53, ATPG may be executed by designating the route including the flip-flop 10, the multiplexer 15, the multiplexer 16 and the flip-flop 14.

When the semiconductor integrated circuit 1 is used as a system, “0” may be input as the selection signal SEL1 to the multiplexer 15. At this time, the selection signal SEL2 to be input to the multiplexer 16 may be either 0 or 1.

As described above, the test circuit 13A of the modification enables the transition test on the wiring 53 by adding the multiplexer 16 to the test circuit 13 of FIG. 3. The wiring 53 is configured to include the wiring 52 of FIG. 3.

As a result, the scan test circuit of the modification enables the wiring 52 excluded from targets of the transition test in FIG. 3 to be set as a target of the transition test. That is, in the semiconductor integrated circuit 1 of the present modification, all the wirings between the flip-flop 10 and the flip-flop 12 can he handled as targets of the transition test.

### Second Embodiment

Next, a second embodiment will be described.

In the second embodiment, a flip-flop of a system is diverted as a flip-flop for making a muhicycle path route into single-cycle paths.

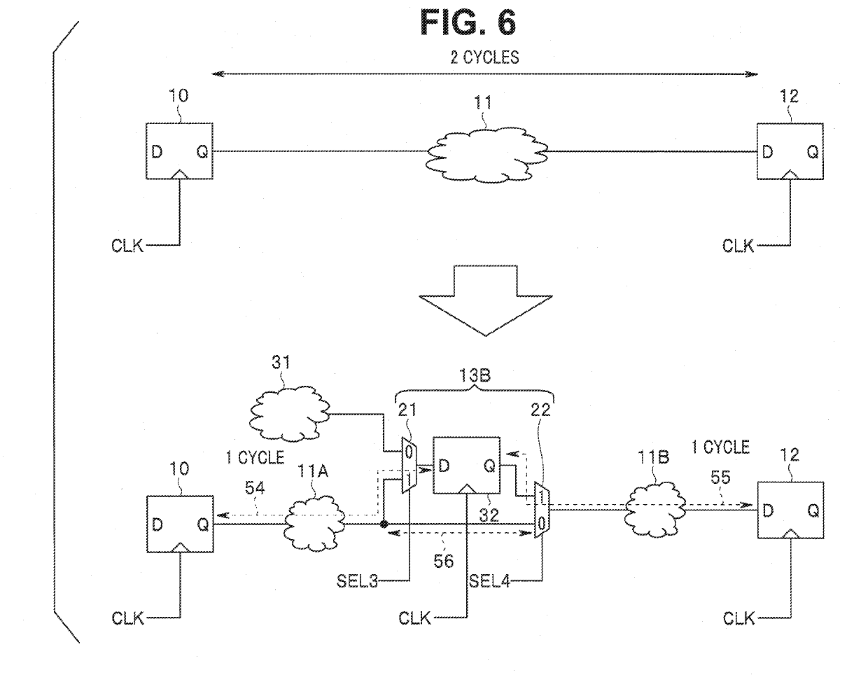

FIG. 6 is a diagram showing an example of a scan test circuit according to the second embodiment. In FIG. 6, components similar to the components in FIG. 3 are represented by the same reference signs, and description on the components is omitted.

A semiconductor integrated circuit 1 of the present embodiment includes system 31 and a flip-flop 32 to which an output of the system 31 is input. The scan test circuit uses the flip-flop 32.

In the second embodiment, two multiplexers 21 and 22 are added as a test circuit 13B. The multiplexer 21 is added on a front stage of the flip-flop 32, and the multiplexer 22 is added on a rear stage of the flip-flop 32.

Based on a selection signal SEL3, the multiplexer 21 outputs one of an. output of the combinational circuit 11A and an output of the system 31 to the flip-flop 32. Based on a selection signal SEL4, the multiplexer 22 outputs one of the output of the combinational circuit 11A and an output of the flip-flop 32 to the combinational circuit 11B.

More specifically, when the selection signal SEL3 is equal to “0”, the multiplexer 21 outputs the output of the system 31 to the flip-flop 32, and when the selection signal SEL3 is equal to “1”, the multiplexer 21 outputs the output of the combinational circuit 11A to the flip-flop 32.

When the selection signal SEL4 is equal to “0”, the multiplexer 22 outputs the output of the combinational circuit 11A to the combinational circuit 11B, and when the selection signal SEL4 is equal to “1”, the multiplexer 22 outputs the output of the flip-flop 32 to the: combinational circuit 11B.

When “1” is input as the selection signals SEL3 and SEL4 to the multiplexers 21 and 22, it is possible to perform the transition test on a wiring 54 between the flip-flop 10 and the flip-flop 32 and a wiring between the flip-flop 32 and the flip-flop 12, which are divided into single-cycle paths. When the semiconductor integrated circuit 1 is used as a system, “0” may be input as the selection signals SEL3 and SEL4 to the multiplexers 21 and 22.

As a result, for each of the divided paths, for example, in the example of FIG. 6, it is possible to individually perform failure detection on each of the wiring 54 and the wiring 55, and also it is possible to perform failure detection as an entire path. Since the wiring 55 is sufficiently short, the timing of the wiring 55 is negligible.

In the first embodiment, the flip-flop 14 and the multiplexer 15 are added as the test circuit 13. However, the second embodiment is configured such that the two multiplexers 21 and 22 are added as the test circuit 13B. Furthermore, the flip-flop 32 of the system is diverted as the flip-flop for dividing the multicycle path into single-cycle paths. As a result, the circuit scale of the semiconductor integrated circuit of the second embodiment can be reduced as compared with the semiconductor integrated circuit of the first embodiment.

### (Modification)

Next, a modification of the second embodiment will be described.

In the second embodiment, the wiring 55 is excluded from targets of the transition test. However, in the modification, a scan test circuit that allows all the wirings of the multicycle path to be subjected to the transition test will be described.

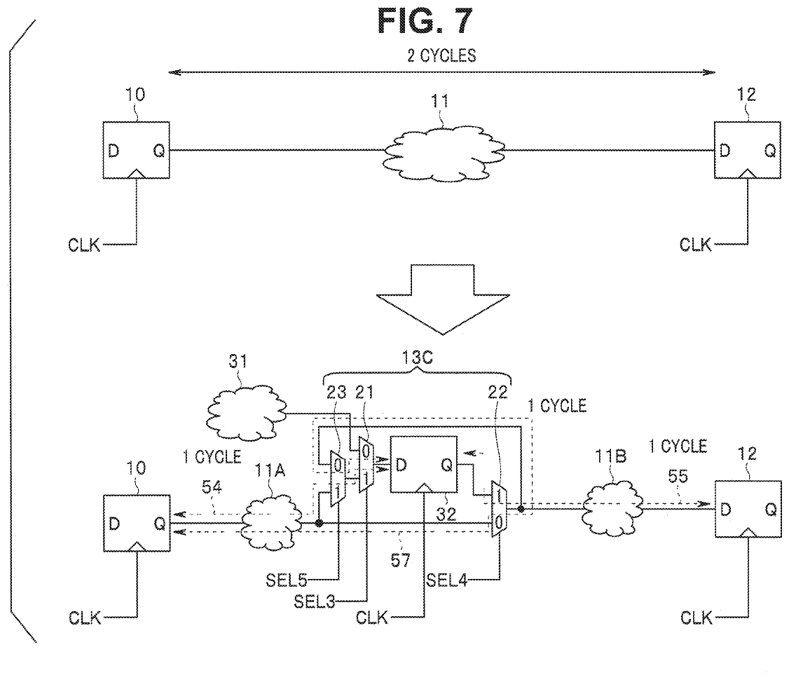

FIG. 7 is a diagram showing an example of a scan test circuit according to the modification of the second embodiment. Note that in FIG. 7, components similar to the components in FIG. 6 are represented by the same reference signs, and description on the components is omitted.

A test circuit 13C according to the modification of the second embodiment is configured by adding a multiplexer 23 to the multiplexers 21 and 22 of the test circuit 13B in FIG. 6. An output of the combinational circuit 11A is input to one input terminal of the multiplexer 23, and an output of the multiplexer 22 is input to the other input terminal of the multiplexer 23. Based on a selection signal SEL5, the multiplexer 23 outputs the output of the combinational circuit 11A or the output of the multiplexer 22 to the multiplexer 21.

More specifically, when the selection signal SEL5 is equal to “0”, the multiplexer 23 outputs the output of the multiplexer 22 to the multiplexer 21, and when the selection signal SEL5 is equal to “1”, the multiplexer 23 outputs the output of the combinational circuit 11A to the multiplexer 21.

When “1” is input as the selection signals SEL3, SEL4 and SEL5 to the muitiplexers 21, 22 and 23, as in the case of the second embodiment, it is possible to perform the transition test on the wiring 54 between the flip-flop 10 and the flip-flop 32 and the transition test on the wiring 55 between the flip-flop 32 and the flip-flop 12.

On the other hand, when “0” is input as the selection signal SEL3 to the multiplexer 21 and “1” is input as the selection signals SEL4 and SEL5, to the multiplexers 22 and 23, the route including the flip-flop 10, the multiplexer 22, the multiplexer 23, the multiplexer 21, and the flip-flop 32 becomes effective, which makes it possible to perform the transition test on a wiring 57. Note that in order to realize the transition test on the wiring 57, ATPG may be executed by designating the route including the flip-flop 10, the multiplexer 22, the multiplexer 23, the multiplexer 21 and the flip-flop 32.

When the semiconductor integrated circuit 1 is used as a system, “0” is input as the selection signals SEL3 and SEL4 to the multiplexers 21 and 22. At this time, the selection signal SEL5 input to the multiplexer 23 may be either “0” or “1”.

In this way, the test circuit 13C of the modification enables the transition test on the wiring 57 by adding the multiplexer 23 to the test circuit 13B of FIG 6. The wiring 57 is configured to include a wiring 56 of FIG. 6.

As a result, the scan test circuit of the modification enables the wiring 56 excluded from targets of the transition test in FIG. 6 to be subjected to the transition test. That is, in the semiconductor integrated circuit of the modification, all the wirings between the flip-flop 10 and the flip-flop 12 can be handled as targets of the transition test.

Note that the respective steps in the flowchart in the present specification may be changed in execution order, multiple steps may be simultaneously executed, or the steps may be executed in a different order for each execution unless conflicting with the properties of the steps.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing front the spirit of the inventions. The accompanying claims and their equivalents are intended to cover such forms or modifications as would fall within the scope and spirit of the inventions.

What is claimed is:

1. A design method for a scan circuit, the method comprising:
reading timing constraint information, a net list, and layout information to extract a multicycie path route from routes existing in a semiconductor integrated circuit;
dividing the multicycle path route extracted by a number of cycles; and
adding a test circuit at each of locations divided by the number of cycles.

2. A non-transitory computer-readable recording medium in which a design program for a scan circuit is recorded, the program comprising:
reading timing constraint information, a net list, and layout information to extract a multicycle path route from routes existing in a semiconductor integrated circuit;
dividing the multicycie path route extracted by a number of cycles; and
adding a test circuit at each of locations divided by a number of cycles.

3. A semiconductor integrated circuit comprising:
a plurality of logic circuits in which a logic circuit provided in a multicycie path route is divided by a number of cycles; and
a test circuit added between the plurality of logic circuits.

4. The semiconductor integrated circuit according to claim 3, wherein the test circuit comprises a flip-flop, and a first multiplexer including an input connected to an output of the flip-flop.

5. The semiconductor integrated circuit according to claim 4, wherein the test circuit further comprises a second multiplexer including an output connected to an input of the flip-flop.

6. The semiconductor integrated circuit according to claim 3, wherein the test circuit comprises a first multiplexer, a flip-flop that includes an input connected to an output of the first multiplexer and is used in a system of the semiconductor integrated circuit, and a second multiplexer including an input connected to an output of the flip-flop.

7. The semiconductor integrated circuit according to claim 6, wherein the test circuit further comprises a third multiplexer including an output connected to an input of the first multiplexer.
